(19) United States
(12) Patent Application Publication
(10) Pub. No.: US 2003/0129535 A1
(43) Pub. Date: Jul. 10, 2003

(54) Photosensitive thermosetting resin composition

(76) Inventor: Ming-Jen Tzou, Taipei (TW)

Correspondence Address: STEVENS, DAVIS, MILLER & MOSHER, L.L.P., Suite 850, 1615 L Street, N.W., Washington, DC, 20036, US

(21) Appl. No.: 09/985,816

(22) Filed: Nov. 6, 2001

(51) Int. Cl. G03F 7/028; G03F 7/40

(52) U.S. Cl. 430/280.1; 430/277.1; 430/315; 430/311; 430/330

(57) ABSTRACT

A photosensitive thermosetting resin composition has the following essential ingredients: a photopolymerizable prepolymer which is prepared by reacting epoxy resin containing at least two epoxy groups with mono-carboxyl acid [(A2)] containing a vinyl group, and then reacting with saturated or unsaturated polybasic acid anhydride; a thinner, which is selected from photopolymerizable vinyl monomer and/or organic solvent, alone or in combination; a photopolymerizable initiator; an epoxy resin including a soluble crystal state epoxy resin which contains two epoxy groups and is not soluble in the utilized thinner at room temperature but soluble at 60˜80 .degree.C. and/or an epoxy resin which contains at least two epoxy groups and is soluble in the utilized thinner at room temperature; and an inorganic filler.

### BACKGROUND OF THE INVENTION

1. Field of the Present Invention The present invention relates to a novel photopolymerizable composition; more particularly, it relates to a photopolymerizable composition used as a solder resist for printed circuit board fabrication. In ultraviolet ray curing, the photopolymerizable composition owns distinguished characteristics of high sensitivity, high resolution (up to 25 μm) and quick curing, especially the formed film after curing owns excellent physical characters such as tin solder heat resistance, electroless gold plating resistance, electrical character, and mechanical strength; in addition, the weak alkali aqueous solution can be used for developing, and its developing effect is extraordinary.

2. Background of the Present Invention

In recent years, there is a trend for the electronic product toward lighter, thinner, shorter, smaller, and highly-condensed one; in addition, the electronic fabricating technique requests mass integration, high pin number, microminiaturization so as to make it a necessity for solder resist ink to have higher resolution, accuracy, and liability. Therefore, the improvement of solder resist ink keeps progressing continuously; some disclosures have applied for patent, wherein there are two major types: dry film type and liquid type.

In view of the dry film type solder resist ink, Japanese Patent No. 57-55914 discloses a dry film photosensitive resin composition containing ethyl urethane-diacrylate, linear polymer, and photosensitive agent. Said dry film type solder resist ink is apt to produce defects of tin solder heat resistance and bad adhesion while utilized in highly condensed printed circuit board. On the other hand, in view of the liquid type solder resist ink, the Great Britain Patent Application No. 2032939A discloses a photopolymerizable prepolymer containing a solid or semi-solid state reaction product of a multi-epoxy group compound alkenyl bond unsaturated carboxyl acid, an inert inorganic filler, a photopolymerizable initiator, and a volatile organic solvent. The aforementioned component is an ultraviolet ray curing component but not a thermosetting component, so it is apt to suffer defects on adhesion, tin solder heat resistance, and insulation resistance while utilized in printed circuit board. In addition, other prior art has disclosed a solder resist ink composition of which the unexposed area is developed by organic solvent which causes environmental pollution, risk of fire, and hazard to human body. In order to solve said problems caused by the use of solvent, some patents disclose a composition which is mainly composed of a weak alkali aqueous solution developed solder resist ink, for example, U.S. Pat. No. 4,918,150 discloses a photopolymerizable prepolymer composition (a compound, containing at least two unsaturated alkenyl bonds, obtained from the reaction of linear phenol novolak or linear cresol novolak resin with unsaturated monobasic acid and polybasic acid anhydride), of which the polybasic acid anhydride reacts to produce an acid group which is dissolved in weak alkali aqueous solution so as to accomplish developing effect; the solder resist ink thereof owns bad developing capability and is apt to suffer electrolysis corrosion due to the affect of the reaction ratio between polybasic acid anhydride and epoxy resin. So, some patents have also disclosed that by using a granular epoxy compound (which is hard to dissolve), the photosensitivity is improved and the reaction with photopolymerizable prepolymer is decreased; however, a higher acid value is required to make photosensitive prepolymer easy to dissolve in weak alkali aqueous solution, which consequently causes the decrease of electroless gold plating resistance capability; besides, the epoxy compound (which is hard to dissolve) is impossible to completely disperse even after being heated to melted state since the limit of the shaped net structure caused by photocuring, which consequently decreases the opportunity for the photopolymerizable prepolymer to completely react so as to adversely reduce the heat resistance.

### SUMMARY OF THE INVENTION

The objects of the present invention are to solve problems and defects of said liquid solder resist ink and to provide a novel photosensitive thermosetting resin composition which owns distinguished solder heat resistance, electroless gold plating resistance, resolution, weak alkali aqueous solution developing capability, ultraviolet ray curing sensitivity, chemical resistance, flexibility, adhesion, and electric character; in addition, it owns excellent characteristics of brilliant surface and transparent outlooking.

The present invention discloses a photosensitive thermosetting resin composition comprising:

(A) a photopolymerizable prepolymer (formula I), which is prepared by reacting epoxy resin (A1) containing at least two epoxy groups with mono-carboxyl acid (A2) containing a vinyl group, and then reacting with saturated or unsaturated polybasic acid anhydride (A3);

(B) a thinner, which is photopolymerizable vinyl monomer (B 1) and/or organic solvent (B2);

(C) a photopolymerizable initiator;

(D) an epoxy resin, comprising a soluble crystal state epoxy resin (DI) which contains two epoxy groups and is not soluble in the utilized thinner at room temperature but soluble at 60˜80 .degree.C. and/or an epoxy resin (D2) which contains at least two epoxy groups and is soluble in the utilized thinner at room temperature; and

(E) an inorganic filler.

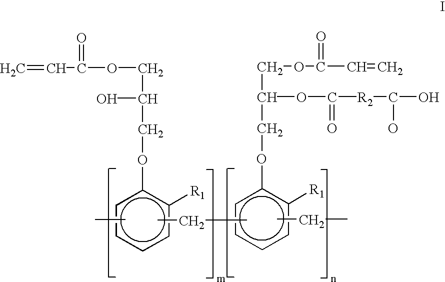

where m and n are integer, m+n≧20

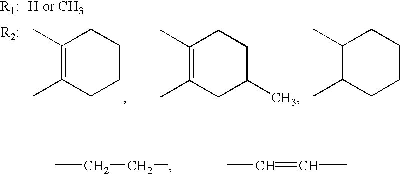

### DETAILED DESCRITION OF THE PREFERRED EMBODIMENTS

The photosensitive thermosetting resin component is a soluble crystal state epoxy resin which can be dissolved in a thinner at 60˜80 .degree C.; especially in circuit board printing, the epoxy resin exists in the composition as crystallization state with a rather low solubility to the thinner; during pre-bake procedure (at a temperature of 60˜80 degree C.), the resin can be dissolved in the thinner; after pre-bake and cooling down, the resin is evenly dispersed in the component as micro-crystal state (grain diameter is below 0.2 μm), which can refrain from the limit of shaped net structure after photoreaction so as to not only increase the reaction efficiency with prepolymer (A) at thermosetting, but also increase the heat resistance of the ink after setting. In addition, the photosensitive thermosetting component of the present invention exists as micro-crystal state, which decreases the tangle with photopolymerizable prepolymer and owns characteristics of being not soluble in weak alkali developing solution, thereby the unphotocured portion shows satisfying developing capability and the photocured portion does not decrease its sensitivity, concurrently it has excellent resolution (it can reach 25 μm); at the post-curing procedure, the micro-crystal epoxy resin can be dissolved and form copolymer with photopolymerizable prepolymer (A). Due to that the epoxy resin is dispersed in molecular state and in micro-crystal of below 0.2 μm, its copolymer formed with prepolymer (A) has distinguished characteristics; furthermore, due to that the resin structure has characteristics, such as high density and low molecular weight and complete and quick reaction, of hydroxide group, the composition has excellent adhesion and heat resistance.

In addition, the comparative data of state changing in solder resist mask layer fabrication procedures between the present invention and the other epoxy resins are tabulated as follows, which helps explain the distinguished characteristics of the photosensitive thermosetting composition of the present invention on providing the need of fabricating the solder resist mask layer of printed circuit board.

Comparative table of state changing of various epoxy resins on solder resist mask layer fabricating procedures

| | | | | | |
|---|---|---|---|---|---|
| Fabricating | Printing stage | Pre-bake stage | Photocuring | Developing | Beginning of |
| procedures of solder | | | stage | stage | post-bake |
| resist mask layer | | | | | |
| Powder epoxy resin | 5˜10 μm | 5˜10 μm | 5˜10 μm | 5˜10 μm | 5˜10 μm melted |
| which is hard to | dispersed | dispersed | dipersed | dispersed | liquid drops |
| dissolve (such as | powder | powder | powder | powder | |
| TEPIC) | | | | | |
| Soluble solid epoxy | Molecular state | Molecular state | Molecular state | Molecular state | Molecular state |
| resin (such as | dispersed liquid | dispersed liquid | dispersed liquid | dispersed liquid | dispersed liquid |
| NPCN-704) | | | | | |
| Soluble crystal state | 5˜10 μm | Molecular state | Below 0.2 μm | Belos 0.2 μm | Below 0.2 μm |
| epoxy resin (such as | dispersed | dispersed liquid | micro-crystal | micro-crystal | melted liquid |
| EX-100) | powder | | | | drops |

Note:
TEPIC is a product of Nissan Chemical Industries Ltd.
NPCN-704, EX-100 are products of Nan Ya Plastics Corp. Ltd.

The structural composition of the photosensitive thermosetting resin of the present invention is described in detail as follows:

the photosensitive thermosetting resin composition of the present invention is obtained by the polymerization of a photopolymerizable prepolymer (A), a thinner (B), a photopolymerizable initiator (C), an epoxy resin (D), and an inorganic filler (E).

The photopolymerizable prepolymer (A) is prepared by the polymerization of epoxy group compound (A1) containing at least two epoxy groups, mono-carboxyl acid (A2) containing at least one vinyl group, and saturated or unsaturated polybasic acid anhydride (A3); wherein the epoxy group compound (A1) containing at least two epoxy groups is selected from one of the following: phenol novolak epoxy resin, cresol novolak epoxy resin, halogenated phenol novolak epoxy resin, bisphenol A epoxy resin, bisphenol F epoxy resin, triphenol methane epoxy resin, or tetrabromo bisphenol A epoxy resin; most preferably phenol novolak epoxy resin, or cresol novolak epoxy resin.

The mono-carboxyl acid (A2) containing at least one vinyl group is selected from one of the following: acrylic acid, methyl acrylic acid, crotonic acid, or cinnamon bark acid; most preferably, as shown in Example, acrylic acid.

The saturated or unsaturated polybasic acid anhydride (A3) is selected from one of the following: succinic anhydride, hexahydrobenzene dimethyl anhydride, methyl hexahydrobenzene dimethyl anhydride, tetrahydrobenzene dimethyl anhydride, or maleic anhydride; most preferably, as shown in Example, tetrahydrobenzene dimethyl anhydride.

The best result can be obtained at the following described range for the amount and ratio of each component: the amounts of epoxy group compound (A1) and of mono-carboxyl acid (A2) containing one vinyl group in the photopolymerizable prepolymer composition (A) are that 0.5 to 1.2 moles of mono-carboxyl acid (A2) containing one vinyl group, based on epoxy group compound (A1), is used for each equivalent of epoxy group compound (A1), most preferably 0.9 to 1.1 moles; and, 0.1 to 1.0 moles of polybasic acid anhydride (A3), based on said epoxy group compound (A1), is used for each equivalent of epoxy group, most preferably 0.3 to 0.8 moles.

The photopolymerizable prepolymer (A) of the present invention is obtained by reacting an epoxy resin (A1) containing two or more than two epoxy groups with a mono-carboxyl acid (A2) containing one vinyl group, of which reaction the solvent is used for dilution and the activator is selected from one of the following: phosphorus tribenzene, triethylamine, or methyl triethyl ammonium chloride, most preferably phosphorus tribenzene; the amount of activator is preferably 0.1 to 1.0 weight percentage of total weight of reaction mixture; in order to refrain from prepolymerization, a heat polymerization inhibitor such as hydroquinone, or hydroquinone dimethyl ether or the like is added, of which the added quantity is preferably 0.01 to 1.0 weight percentage of that of the reaction mixture; the reaction temperature is preferably 80 to 120 .degree.C. and the reaction time is 6 to 24 hours; then, the reaction product thereof further reacts with the saturated or unsaturated polybasic acid anhydride (A3) at a reaction temperature of 80˜130 .degree.C. preferably and for 4˜16 hours of reaction time.

The acid value (mg KOH/g) of the photopolymerizable prepolymer (A) obtained from said process is preferably at the range of 30 to 120, most preferably 50 to 100.

The photopolymerizable prepolymer (A) content in the composition of the present invention is more preferably 40 to 70 wt %, most preferably 45 to 65 wt %.

The thinner, which is selected from photopolymerizable vinyl monomer (B1) and/or organic solvent (B2), alone or in combination, depending on the real situation. The photopolymerizable vinyl monomer (B1), comprising acrylate of melamine, is selected from the following:

Hydroxyalkyl acrylate such as 2-hydroxyl ethyl acrylate, or 2-hydroxyl butyl acrylate;

Acrylic or diacrylic compound of binary alcohol (such as ethylene glycol, methoxy tetraethylene glycol, polyethylene glycol, propylene glycol);

Alkyl amine acrylic acid compound such as acrylic acid-N, N-dimethyl amine ethyl ester;

Polyfunctional group acrylate of polyhydric alcohol (such as hexyl glycol, trimethylol propane, isoamyl tetraol, diisoamyl tetraol) or of ethylene oxide, or of propylene oxide (can be the adduct of itself);

Acrylate of epoxypropyl ether (such as glycerindiepoxy propyl ether, trimethylol propane diepoxy propyl ether, triepoxy propyl isocyanurate);

wherein the acrylate of melamine or the polyfunctional group acrylate of isoamyl tetraol, diisoamyl tetraol are the most preferable.

The content of the aforementioned photopolymerizable vinyl monomer (B1) in the composition of the present invention is more preferably 130 wt %, most preferably 1˜10 wt %.

The organic solvent (B2) of the present invention is selected from one of the following: propylene carbonate, butyl cellosolve, butyl cellosolve acetate, toluene, xylene, butyl carbitol acetate, cyclohexanone, propylene glycol monomethyl ether, dipropylene glycol diethyl ether, methyl carbitol acetate. The preferred embodiments in Example are propylene carbonate and butyl cellosolve acetate. The amount used in the present invention is more preferably 5˜60 wt %, most preferably 10˜50 wt %.

As for the photopolymerizable initiator (C), a conventional photo initiator is used. It can be selected from one of the following: benzoin methyl ether, benzoin isopropyl ether, 2,2-dimethoxy-2-phenyl acetophenone, 1,1-dichloro acetophenone, 1-hydroxycyclohexy phenyl ketone, 2-methyl-1-[4-(methylthio)phenyl]-2-morpholino-propane-1, N,N-dimethyl aminoacetophenone, 2,4-dimethylthioxanthone, 2,4-diethylthioxanthone, 2-chlorothioxanthone, 2,4-diisopropylthioxanthone, acetophenone dimethyl ketal, benzyl dimethyl ketal, methyl benzophenone, 4,4′-dichlorobenzophenone, 4,4′-diethylaminobenzophenone, 4-methyl benzoil diphenyl phosphine oxide. Said compounds can be used alone or in combination of two or more thereof; most preferably is the combination of 2-methyl-1-[4-(methylthio)phenyl]-2-morpholino-propane-1 and 2,4-diethylthioxanthone. The amount of the photopolymerizable initiator (C) used in the present invention is more preferably 0.5˜10 wt %, most preferably 1˜8 wt %.

The epoxy resin (D) is composed of a crystal state epoxy resin (D1) which contains two epoxy groups and is not soluble in the utilized thinner at room temperature but soluble at 60˜80 .degree.C. and/or an epoxy resin (D2) which contains at least two epoxy groups and is soluble in the utilized thinner at room temperature, wherein the soluble crystal state epoxy resin (Dl) is the characteristic of the present invention. Hydroquinone is used in the preferred embodiment of Example, which is a product of Nan Ya Plastics Corp. Ltd., with a structure as follows (Formula II):

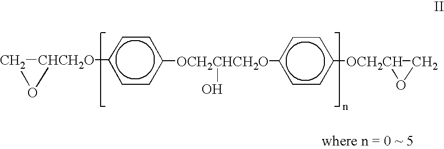

The content of the crystal state epoxy resin (DI) in the composition of the present invention is more preferably 2˜10 wt %, most preferably 3˜8 wt %. This kind of epoxy resin is crystalline state at room temperature, which needs to be through stirred and mixed and ground to below 10 μm of grain diameter before being added to the composition.

As for the epoxy resin (D2), the preferred embodiment in Example is one of the following: triglycidal isocyanate, phenol novolak epoxy resin, cresol novolak epoxy resin, halogenated phenol novolak epoxy resin, Bisphenol A epoxy resin, Bisphenol F epoxy resin, triphenyl methane epoxy resin, or tetrabromo Bisphenol A epoxy resin.

The content of the aforementioned epoxy resin (D2) in the composition is preferably 1˜15 wt %, more preferably 3˜8 wt %.

The main filler used in the composition of the present invention is a widely used inorganic filler (E) such as talc powder, magnesium carbonate, calcium carbonate, aluminum oxide, silicon oxide powder, and barium sulfate. These compounds are used in combination. The amount of the inorganic filler used in the present invention is more preferably 10˜40 wt %, most preferably 15˜30 wt %.

In addition, the composition of the present invention includes conventional additives such as tonner, dye, defoamer, leveling agent, thickening agent, adhesion accelerator.

In order to have the contents and characteristics of the present invention be understood further, Examples and Comparative examples are described below to furnish a specific idea about its process, procedure, and outstanding characteristic.

### EXAMPLE

The following examples are given to illustrate characteristics of the present invention but not to limit the invention.

The applied prescription and proportion of the Example is to select Photopolymerizable prepolymer (A): of which the preparation is to have 205 parts of NPCN-704 (EEW: 205, product of Nan Ya Plastics Co. Ltd.) and 167.2 parts of butyl cellosolve acetate [thinner (B2)] be stirred and heated to 100 degree C. and dissolved in a reaction tank; then, add 72 parts of acrylic acid, 1.5 parts of phosphorus tribenzene, 0.15 parts of hydroquinone and stir at 100 degree C. for 12 hours; next, add 106.4 parts of tetrahydrobenzene dimethyl anhydride to react at 100 degree C. for 10 hours; the acid value of the obtained prepolymer (A) is 88.1 mgKOH/g, and the solid component is 62.5 percent;

Thinner (B 1): diisoamyl tetraol pentaacrylate;

Thinner (B2): butyl cellosolve acetate;

Phtopolymerization initiator (C): 2-methyl-1-[4-(methylthio)phenyl]-2-morpholino-propane-1 (Irgacure 907, a product of Ciba Geigy) and 2,4-diethylthioxanthone (DETX-S, a product of Nippon Kayaku Co. Ltd.);

Epoxy resin (DI): hydroquinone epoxy resin (EX-100, a product of Nan Ya Plastics Co. Ltd.);

Epoxy resin (D2): cresol novolak epoxy resin (NPCN-704, a product of Nan Ya Plastics Co. Ltd.);

Inorganic filler (E): barium sulfate (grain diameter is lower than 10 em), silicon oxide powder (grain diameter is lower than 10 μm);

Heterocyclic epoxy resin: Tris (epoxypropyl) Isocyanurate (TEPIC, a product of Nissan Chemical Industries Ltd.);

Defoamer: AC-300 (a product of Kyoeisha Chemical Co. Ltd.);

Tonner: benzyl dimethyl green;

Said “part” means the amount of additive based on weight.

In the following Example 13 and Comparative example 13, the aforementioned composition is thoroughly stirred; then, ground by a 3-Roller Mill so as to obtain a solder resist mask layer composition with grain diameter smaller than 10 μm; the obtained photosensitive thermosetting resin composition of the present invention is further evenly coated on a printed circuit board having the copper opening and wire pattern by silk screen printing method, shower coating method, spraying method, or roller method to form a coated layer with a thickness of 2030 gm; after pre-bake, a negative film having photoresist pattern is closely adhered to the coated layer; and then through procedures of being exposed to ultraviolet rays and of being developed for the unexposed portion by the developing solution, a solder resist pattern is produced; and then by heating, said epoxy compound in the composition is solidified and a solder resist mask layer is obtained.

| | |
|---|---|
| Example 1 | |
| Photopolymerizable prepolymer (A) | 55.0 parts |
| Diisoamyl tetraol pentaacrylate | 6.5 parts |
| 2-methyl-1-[4-(methylthio)phenyl]-2-morpholino-propane-1 | 5.0 parts |
| 2,4-diethylthioxanthone | 1.0 part |
| Hydroquinone epoxy resin | 7.0 parts |
| Cresol novolak epoxy resin | 3.0 parts |
| Barium sulfate | 11.0 parts |
| Silicon oxide powder | 10.0 parts |
| Benzyl dimethyl green | 0.5 parts |
| AC-300 | 1.0 part |
| Total | 100.0 parts |
| Example 2 | |
| Photopolymerizable prepolymer (A) | 55.0 parts |
| Diisoamyl tetraol pentaacrylate | 6.5 parts |
| 2-methyl-1-[4-(methylthio)phenyl]-2-morpholino-propane-1 | 5.0 parts |
| 2,4-diethylthioxanthone | 1.0 part |
| Hydroquinone epoxy resin | 5.0 parts |
| Cresol novolak epoxy resin | 5.0 parts |
| Barium sulfate | 11.0 parts |
| Silicon oxide powder | 10.0 parts |
| Benzyl dimethyl green | 0.5 parts |
| AC-300 | 1.0 part |
| Total | 100.0 parts |
| Example 3 | |
| Photopolymerizable prepolymer (A) | 55.0 parts |
| Diisoamyl tetraol pentaacrylate | 6.5 parts |
| 2-methyl-1-[4-(methylthio)phenyl]-2-morpholino-propane-1 | 5.0 parts |
| 2,4-diethylthioxanthone | 1.0 part |
| Hydroquinone epoxy resin | 3.0 parts |
| Cresol novolak epoxy resin | 7.0 parts |
| Barium sulfate | 11.0 parts |
| Silicon oxide powder | 10.0 parts |
| Benzyl dimethyl green | 0.5 parts |
| AC-300 | 1.0 part |
| Total | 100.0 parts |
| Comparative example 1 | |
| Photopolymerizable prepolymer (A) | 55.0 parts |
| Diisoamyl tetraol pentaacrylate | 6.5 parts |
| 2-methyl-1-[4-(methylthio)phenyl]-2-morpholino-propane-1 | 5.0 parts |
| 2,4-diethylthioxanthone | 1.0 part |
| Heterocyclic epoxy resin | 5.0 parts |
| Cresol novolak epoxy resin | 5.0 parts |
| Barium sulfate | 11.0 parts |
| Silicon oxide powder | 10.0 parts |
| Benzyl dimethyl green | 0.5 parts |
| AC-300 | 1.0 part |
| Total | 100.0 parts |
| Comparative example 2 | |
| Photopolymerizable prepolymer (A) | 55.0 parts |
| Diisoamyl tetraol pentaacrylate | 6.5 parts |
| 2-methyl-1-[4-(methylthio)phenyl]-2-morpholino-propane-1 | 5.0 parts |
| 2,4-diethylthioxanthone | 1.0 part |
| Cresol novolak epoxy resin | 10.0 parts |
| Barium sulfate | 11.0 parts |
| Silicon oxide powder | 10.0 parts |
| Benzyl dimethyl green | 0.5 parts |
| AC-300 | 1.0 part |
| Total | 100.0 parts |
| Comparative example 3 | |
| Photopolymerizable prepolymer (A) | 55.0 parts |
| Diisoamyl tetraol pentaacrylate | 6.5 parts |
| 2-methyl-1-[4-(methylthio)phenyl]-2-morpholino-propane-1 | 5.0 parts |
| 2,4-diethylthioxanthone | 1.0 part |
| Heterocyclic epoxy resin | 10.0 parts |
| Barium sulfate | 11.0 parts |
| Silicon oxide powder | 10.0 parts |
| Benzyl dimethyl green | 0.5 parts |
| AC-300 | 1.0 part |
| Total | 100.0 parts |

Effects of the Present Invention

The obtained composition of the present invention is blended and ground by a 3-Roll Mill until the grain diameter is below 10 μm and then spread on the printed circuit board which is afterwards tested for tackiness-after-drying before developing, and measured for maximum pre-bake area while developing, and tested for adhesion, pencil hardness, solder heat resistance, electroless nickel (gold) plating resistance, acid resistance, base resistance, solvent resistance, boiling water resistance, high pressure boiling resistance after the post-bake. While measuring the maximum pre-bake area, the bake temperature is 80 degree C. and the bake time is 50 minutes, 60 minutes, 70 minutes, and 80 minutes. While testing other physical characteristics, the temperature is 80 degree C. and the time is 40 minutes. Then, a negative film having photoresist pattern is closely adhered to the coated layer of the printed circuit board which has been cooled down to room temperature (about 22˜25 degree C.), which is irradiated by an ultraviolet exposure device (HMW-680GW type, a product of RC Corp. Ltd.) with an energy of about 500 mJ/cm² and is then sprayed by a 0.9˜1.1% NaOH₂ aqueous solution at a pressure of 2.0 kg/cm² and a liquid temperature of 31 degree C. for 60 seconds of developing so as to dissolve and expel the unexposed area (other kinds of weak base aqueous solution can also be used); finally, in order to let the epoxy resin undergo a complete ring-opening linkage, the post-bake is done at 150 degree C. of bake temperature and 30˜60 minutes of bake time so as to let solidify completely. The test and measuring methods are described as follows:

1. Tackiness after drying

After the composition has been coated on the printed circuit board (thickness of coating is 20˜30 μm) and pre-baked, the coated layer is touched by finger of which the feeling of tackiness can be classified into three various degrees which are represented by following symbols.

O: No tackiness

Δ: Slight tackiness

X: Severe tackiness

2. Maximum Pre-Bake Area

After the composition has been coated on the printed circuit board (thickness of coating is 20˜30 μm, totally four test pieces) and baked at 80 .degree.C. for 70 minutes, 80 minutes, 90 minutes independently and cooled down, an 1% Na₂CO₃ aqueous solution with a temperature of 31 .degree.C. and a pressure of 2.0 kg/cm² is sprayed thereto for 60 seconds to develop, i.e., to dissolve and expel said composition coated on the printed circuit board. The following symbols represent the good or the bad of the maximum pre-bake area.

⊚: composition can be expelled completely while baked at 80 degree C. for 80 minutes

O: composition can be expelled completely while baked at 80 degree C. for 70 minutes but not for 80 minutes

Δ: composition can be expelled completely while baked at 80 degree C. for 60 minutes but not for above 70 minutes

X: composition can not be expelled completely while baked at 80 degree C. for 60 minutes

3. Adhesion

According to the testing method regulated by JIS D0202, said composition is coated on the printed circuit board and baked; then use Cross Cutter to cut the coated layer into 100 checks, and a peeling off test is done by using 3M #600 tape. The peeling off condition is evaluated by naked eyes and the following symbols represent either good or bad adhesion.

⊚: 100/100 no peeling off (on copper surface)

O: 1˜5% peeling off (on copper surface)

Δ: 5˜10% peeling off (on copper surface)

X: above 10% peeling off (on copper surface)

4. Solder Heat Resistance

Said composition is coated on the printed circuit board and post-baked, on which a solder assistant is spread in accordance with the method regulated by JIS C6481; next, the sample is dipped into a solder bath at 260 .degree.C. for 10 seconds and cleaned by clean water and then evaluated by naked eyes.

O: no change for coated layer of the composition

Δ: there is a change on gloss and appearance of coated layer of the composition

X: there is peeling off and bulging situation for coated layer of the composition

5. Pencil Hardness

The test piece is made by way of using the same method as that of adhesion. 2B˜9H pencils manufactured by Mitsubishi are ground at their tip until a right angle for each of them is formed and then push the tip of each of them forward at an angle of 45 degrees with a pressure of 1 Kg on the coated layer of the test piece until the surface of the coated layer is damaged; the maximum pencil hardness that does not damage the surface of coated layer represents the hardness of the coated layer.

6. Electroless Nickel (Gold) Plating Resistance

The test piece is first immersed in an acid degrease solution for 3 minutes at 30 degree C. to be degreased; next, immersed in water for 3 minutes to be cleaned; then, the test piece is immersed in water containing 14.3% of (NH4)2SO4 for 3 minutes to proceed soft etching and immersed in cleaning water thereafter for 3 minutes; afterwards, it is immersed in water containing 10 vol % H2SO4 at room temperature for one minute and then cleaned in water for 30 seconds to 1 minutes. Following that, it is immersed in activation solution at 30 degree C. for 7 minutes to be activated and then immersed in water for 3 minutes to be cleaned. The activated test piece is then immersed in nickel plating solution at 85 degree C. for 20 minutes to proceed electroless nickel plating; afterwards, it is immersed in water containing 10 vol % H2SO4 at room temperature for one minute and cleaned by flowing water for 30 seconds to one minute. Then, the test piece is further immersed in gold plating solution at 95 degree C. for 10 minutes to proceed electroless gold plating; thereafter, it is immersed in flowing water for 3 minutes to be cleaned and then in hot water at 60 degree C. for 3 minutes to be further cleaned. After thorough water cleaning and complete drying, a electroless gold plating test piece is finally obtained. The obtained test piece is then proceeded with peeling off test by using cellophane tape and the condition of peeling off of the photoresist is evaluated.

O: no change is observed on the appearance and peeling off of the photoresist

Δ: no change is observed on the appearance of the photoresist despite slight peeling off of the photoresist is observed

X: the photoresist bulges and the board wrinkles; in addition, severe peeling off is observed at peeling off test

7. Acid Resistance

The test piece is made by using the same method as that of adhesion; then, it is immersed in water containing 10 vol % H₂SO₄ at 20 degree C. for 30 minutes and taken out thereafter, of which the acid resistance is evaluated by the status and adhesion of the coated layer.

⊚: no change at all

O: slight change at its surface

Δ: severe change at its surface

X: peeling off occurs to the hardened coated layer

8. Base Resistance

The test piece is made by using the same method as that of adhesion; then, it is immersed in water containing 10 vol % NaOH at 20 degree C. for 30 minutes and taken out thereafter, of which the base resistance is evaluated by the status and adhesion of the coated layer.

⊚: no change at all

O: slight change at its surface

Δ: severe change at its surface

X: peeling off occurs to the hardened coated layer

9. Solvent Resistance

The test piece is made by using the same method as that of adhesion; then, it is immersed in trichloromethane and acetone respectively at 20 degree C. for 30 minutes and taken out thereafter, of which the solvent resistance is evaluated by the status and adhesion of the coated layer.

⊚: no change at all

O: slight change at its surface

Δ: severe change at its surface

X: peeling off occurs to the hardened coated layer

10. Boiling Test

The test piece is made by using the same method as that of adhesion; then, it is immersed in 100 degree C. of boiling water at a pressure of one atm for 5 hours and observed.

⊚: no change at all for coated layer

O: slight change at the surface of coated layer

Δ: severe change at the surface of coated layer

X: peeling off and bulging occur to the coated layer

11. Pressurized Pot Test

The test piece is made by using the same method as that of adhesion; then, it is boiled of steamed at a pressure of 2 atms for 5 hours and observed.

⊚: no change at all for coated layer

O: slight change at the surface of coated layer

Δ: severe change at the surface of coated layer

X: peeling off and bulging occur to the coated layer

Comparison of Physical Characters Between Examples and Comparative Examples

| Test items of | | | | | | |
|---|---|---|---|---|---|---|
| physical | | | | Comparative | Comparative | Comparative |
| characters | Example 1 | Example 2 | Example 3 | example 1 | example 2 | example 3 |
| Tackiness | ◯ | ◯ | ◯ | ◯ | ◯ | ◯ |
| after drying | ⊚ | ⊚ | ◯ | ◯ | X | ◯ |
| Maximum | ⊚ | ⊚ | ◯ | ◯ | X | ◯ |
| pre-bake area | | | | | | |
| Adhesion | ⊚ | ⊚ | ⊚ | ⊚ | ⊚ | ⊚ |
| Solder heat | ◯ | ◯ | ◯ | Δ | X | Δ |
| resistance | | | | | | |
| Pencil | 8H | 8H | 7H | 7H | 7H | 7H |
| hardness | | | | | | |
| Electroless | ◯ | ◯ | ◯ | ◯ | Δ | ◯ |
| nickel(gold) | | | | | | |
| plating resistance | | | | | | |
| Acid | ⊚ | ⊚ | ⊚ | ◯ | Δ | ⊚ |
| resistance | | | | | | |
| Base | ⊚ | ⊚ | ⊚ | ⊚ | ⊚ | ⊚ |
| resistance | | | | | | |
| Solvent | ⊚ | ⊚ | ⊚ | ⊚ | ⊚ | ⊚ |
| resistance | | | | | | |
| Boiling test | ⊚ | ⊚ | ⊚ | ◯ | Δ | ◯ |
| Pressurized | ⊚ | ⊚ | ⊚ | ◯ | X | ◯ |
| pot test | | | | | | |

From the aforementioned results, it is obvious that the soluble crystal state epoxy resin (D1) and soluble type epoxy resin (D2) (such as components of Example 1, Example 2, Example 3) of the present invention do tremendously improve physical characters of the solder resist layer of the printed circuit board.

What is claimed is:

1. A photosensitive thermosetting resin component comprising:
(A) a photopolymerizable prepolymer (formula I), which is prepared by reacting epoxy resin (A1) containing at least two epoxy groups with mono-carboxyl acid (A2) containing a vinyl group, and then reacting with saturated or unsaturated polybasic acid anhydride (A3);
(B) a thinner, which is selected from photopolymerizable vinyl monomer (B 1) and/or organic solvent (B2);
(C) a photopolymerizable initiator;
(D) an epoxy resin, comprising a soluble crystal state epoxy resin (D1) which contains two epoxy groups and is not soluble in the utilized thinner at room temperature but soluble at 60˜80 .degree.C. and/or an epoxy resin (D2) which contains at least two epoxy groups and is soluble in the utilized thinner at room temperature; and
(E) an inorganic filler; 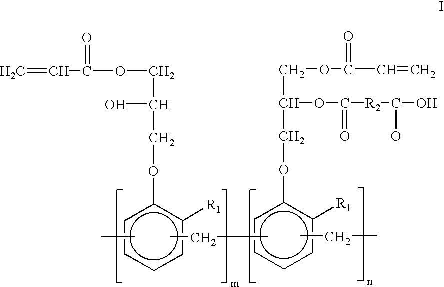
where m and n are integer, m+n≧20

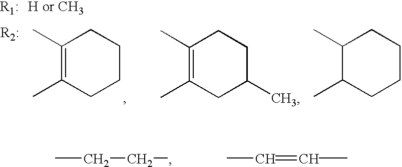

2. A photosensitive thermosetting resin composition as defined in claim 1, wherein the amount of epoxy group compound (A1) and that of mono-carboxyl acid (A2) containing one vinyl group in the photopolymerizable prepolymer composition (A) are that from 0.5 to 1.2 moles of mono-carboxyl acid (A2) containing one vinyl group, based on epoxy group compound (A1), are more preferably used for each equivalent of epoxy group compound (A1), most preferably from 0.9 to 1.1 moles; and, from 0.1 to 1.0 moles of polybasic acid anhydride (A3), based on the hydroxyl group which is a reaction product of said carboxyl group and epoxy group, are more preferably used for each equivalent of hydroxyl group, most preferably from 0.3 to 0.8 moles.

3. A photosensitive thermosetting resin composition as defined in claim 1, wherein the epoxy group compound (A1) containing at least two epoxy groups in the reaction of the photopolymerizable prepolymer (A) is selected from one of the following: phenol novolak epoxy resin, cresol novolak epoxy resin, halogenated phenol novolak epoxy resin, bisphenol A epoxy resin, bisphenol F epoxy resin, triphenol methane epoxy resin, or tetrabromo bisphenol A epoxy resin; as for the mono-carboxyl acid (A2) containing at least one vinyl group is selected from one of the following: acrylic acid, methyl acrylic acid, crotonic acid, cinnamon bark acid; the saturated or unsaturated polybasic acid anhydride (A3) is selected from one of the following: succinic anhydride, hexahydrobenzene dimethyl anhydride, methyl hexahydrobenzene dimethyl anhydride, tetrahydrobenzene dimethyl anhydride, maleic anhydride.

4. A photosensitive thermosetting resin composition as defined in claim 1, wherein the acid value (mg KOH/g) of the photopolymerizable compound (A) is at the range of from 30 to 120, most preferably from 50 to 100; the photopolymerizable prepolymer (A) content in the composition is from 40 to 70 wt %, most preferably from 45 to 65 wt %.

5. A photosensitive thermosetting resin composition as defined in claim 1, wherein the soluble crystal state epoxy resin (D1) exists as a crystal state epoxy resin that is not soluble in the thinner at room temperature and exists as dispersed molecular state that is soluble in the thinner at 60˜80 degree C. and exists as micro-crystal state (grain diameter is below 0.2 μm) that is evenly dispersed in the composition while cooled down to room temperature; the epoxy group compound which fulfils said conditions is hydroquinone epoxy resin of which the content in the composition is more preferably from 2 to 10 wt %, most preferably from 3 to 8 wt %.

6. A photosensitive thermosetting resin composition as defined in claim 1, wherein the soluble epoxy compound (D2) is selected from at least one of the following epoxy resins: triglycidal isocyanate, phenol novolak epoxy resin, cresol novolak epoxy resin, halogenated phenol novolak epoxy resin, Bisphenol A epoxy resin, Bisphenol F epoxy resin, triphenyl methane epoxy resin, or tetrabromo Bisphenol A epoxy resin, of which the content in the composition is more preferably from 1 to 15 wt %, most preferably from 3 to 8 wt %.

7. A photosensitive thermosetting resin composition as defined in claim 1, wherein the thinner (B1) is selected from at least one of the following photopolymerizable vinyl monomers: hydroxyalkyl acrylate such as 2-hydroxyl ethyl acrylate or hydroxyl butyl acrylate; acrylic or diacrylic compound of binary alcohol (such as ethylene glycol, methoxy tetraethylene glycol, polyethylene glycol, propylene glycol); alkyl amine acrylic acid compound such as acrylic acid-N, N-dimethyl amine ethyl ester; polyfunctional group acrylate of polyhydric alcohol (such as hexyl glycol, trimethylol propane, isoamyl tetraol, diisoamyl tetraol) and acrylate ethylene oxide, propylene oxide (can be the adduct of itself); acrylate of epoxypropyl ether (such as glycerindiepoxy propyl ether, trimethylol propane diepoxy propyl ether, triepoxy propyl isocyanurate);
wherein the acrylate of melamine or the polyfunctional group acrylate of isoamyl tetraol, diisoamyl tetraol are the most preferable; and the content of said photopolymerizable vinyl monomer in the composition is more preferably from 1 to 30 wt %, most preferably from 1 to 10 wt %.

8. A photosensitive thermosetting resin composition as defined in claim 1, wherein the thinner (B2) is selected from at least one of the following organic solvents: propylene carbonate, butyl cellosolve, butyl cellosolve acetate, toluene, xylene, butyl carbitol acetate, cyclohexanone, propylene glycol monomethyl ether, dipropylene glycol diethyl ether, methyl carbitol acetate; the amount used in the composition is more preferably from 5 to 60 wt %, most preferably from 10 to 50 wt %.

9. A photosensitive thermosetting resin composition as defined in claim 1, wherein the filler (E) is selected from the following inorganic fillers (used in combination): talc powder, magnesium carbonate, calcium carbonate, aluminum oxide, silicon oxide powder, and barium sulfate; the amount of inorganic filler used in the composition is more preferably from 10 to 40 wt %, most preferably from 15 to 30 wt %.

10. A photosensitive thermosetting resin composition as defined in claim 1, of which the additive that can be additionally selected is one of the following: an aging accelerator, a tonner, a defoamer, a polymerization inhibitor, a thixotropy agent.

11. A fabricating method of forming a solder resist mask layer on a printed circuit board, which evenly coated the photosensitive thermosetting resin composition as defined in claim 1 on a printed circuit board having the copper opening and wire pattern by silk screen printing method, shower coating method, spraying method, or roller method to form a thickness of 20˜30 μm of coated layer; after pre-bake, the coated layer is closely adhered to a negative film having photoresist pattern; and then through the procedures of being exposed to ultraviolet rays and of being developed for the unexposed portion by the developing solution, a solder resist pattern is produced; and then by heating, said epoxy compound in the composition is solidified and a solder resist mask layer is obtained.
